(19) United States
(12) Patent Application Publication
(10) Pub. No.: US 2015/0114560 A1
(43) Pub. Date: Apr. 30, 2015

(54) SUBSTRATE PROCESSING APPARATUS AND LIQUID SUPPLY APPARATUS

(71) Applicant: TOKYO ELECTRON LIMITED, Tokyo (JP)

(72) Inventor: Shigehisa INOUE, Kumamoto (JP)

(21) Appl. No.: 14/521,701

(22) Filed: Oct. 23, 2014

(30) Foreign Application Priority Data
Oct. 25, 2013 (JP) 2013-222545

(51) Int. Cl. H01L 21/67

(52) U.S. Cl. CPC H01L 21/6708
USPC 156/345.21; 239/562

(57) ABSTRACT

A substrate processing includes a holding mechanism, a plurality of nozzles, and an adjusting unit. The holding mechanism rotatably holds a substrate. The nozzles are disposed to be arranged in a diametric direction of the substrate held by the holding mechanism and supply a chemical liquid to the substrate. The adjusting unit supplies a chemical liquid of a first temperature and a chemical liquid of a second temperature to each of the plurality of nozzles in a predetermined ratio, in which the second temperature is higher than the first temperature. The adjusting unit supplies the chemical liquid of the second temperature in a higher ratio to a nozzle disposed at an outer circumference side of the substrate than to a nozzle disposed at a center side of the substrate. In addition, the adjusting unit supplies the chemical liquid of the second temperature in a higher ratio to the nozzle disposed at the outer circumference side of the substrate than to the nozzle disposed at the center side of the substrate. Each of the nozzles supplies a chemical liquid in which the supplied chemical liquid of the first temperature and the supplied chemical liquid of the second temperature are mixed with each other.

### CROSS-REFERENCE TO RELATED APPLICATIONS

This application is based on and claims priority from Japanese Patent Application No. 2013-222545, filed on Oct. 25, 2013 with the Japan Patent Office, the disclosures of which is incorporated herein in its entirety by reference.

### TECHNICAL FIELD

Exemplary embodiments disclosed herein relate to a substrate processing apparatus and a liquid supply apparatus.

### BACKGROUND

Conventionally, a processing of supplying a chemical liquid to a substrate such as, for example, a silicon wafer or a compound semiconductor wafer, is performed in a semiconductor device manufacturing process.

For example, Japanese National Phase Patent Laid-Open Publication No. 2010-528470 discloses a technology in which a nozzle is positioned at a center of a rotating substrate and then an etching liquid such as, for example, HF (hydrogen fluoride), is supplied to the rotating substrate from the nozzle, thereby etching and removing a silicon film formed on the substrate.

### SUMMARY

A substrate processing apparatus according to the present disclosure includes a holding mechanism, a plurality of nozzles, and an adjusting unit. The holding mechanism rotatably holds a substrate. The plurality of nozzles is disposed to be arranged in a diametric direction of the substrate held by the holding mechanism and supplies a chemical liquid to the substrate. The adjusting unit supplies a chemical liquid of a first temperature and a chemical liquid of a second temperature to each of the plurality of nozzles in a predetermined ratio, in which the second temperature is higher than the first temperature. In addition, the adjusting unit supplies the chemical liquid of the second temperature in a higher ratio to the nozzle disposed at the outer circumference side of the substrate than to the nozzle disposed at the center side of the substrate. Each of the nozzles supplies a chemical liquid in which the supplied chemical liquid of the first temperature and the supplied chemical liquid of the second temperature are mixed with each other, to the substrate.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

FIG. 1 is a view illustrating a schematic configuration of a substrate processing system according to an exemplary embodiment.

FIG. 2 is a view illustrating a schematic configuration of a processing unit.

FIG. 3 is a view illustrating configurations of a substrate holding mechanism and a processing fluid supply unit.

FIG. 4A is a view illustrating a relationship between a position on a wafer and an etching rate in a case where an etching liquid is supplied to a center of the wafer while the wafer is rotating.

FIG. 4B is a view illustrating a relationship between a temperature of an etching liquid and a position of a wafer in a first exemplary embodiment.

FIG. 5 is a view illustrating a configuration of a processing fluid supply source.

FIG. 6 is a view illustrating another configuration of the processing fluid supply source.

FIG. 7 is a schematic cross-sectional plan view illustrating an adjusting unit.

FIG. 8 is a cross-sectional view taken along line A-A in FIG. 7.

FIG. 9A is a view illustrating another configuration of the adjusting unit.

FIG. 9B is a view illustrating still another configuration of the adjusting unit.

FIG. 10 is a view illustrating a configuration of a substrate holding mechanism and a processing fluid supply unit according to a second exemplary embodiment.

FIG. 11 is a view illustrating a configuration of an adjusting unit according to a second exemplary embodiment.

FIG. 12 is a view illustrating a configuration of an adjusting unit according to a third exemplary embodiment.

### DETAILED DESCRIPTION

In the following detailed description, reference is made to the accompanying drawings, which form a part hereof. The exemplary embodiments described in the detailed description, drawing, and claims are not meant to be limiting. Other exemplary embodiments may be utilized, and other changes may be made, without departing from the spirit or scope of the subject matter presented here.

There is room for additional improvement in the prior art described above in terms of enhancing an in-plane uniformity of a substrate processing.

For example, in the above-described prior art, the etching liquid supplied to the center of the substrate suffers from reduction in temperature until the etching liquid reaches the outer circumference of the substrate. Thus, an etching rate at the outer circumference of the substrate may be lower than the etching rate at the center of the substrate.

An exemplary embodiment is intended to provide a substrate processing apparatus and a liquid supply apparatus which are capable of enhancing an in-plane uniformity of a substrate processing.

A substrate processing according to an aspect of the present disclosure includes a holding mechanism, a plurality of nozzles, and an adjusting unit. The holding mechanism rotatably holds a substrate. The plurality of nozzles is disposed to be arranged in a diametric direction of the substrate held by the holding mechanism and supply a chemical liquid to the substrate. The adjusting unit supplies a chemical liquid of a first temperature and a chemical liquid of a second temperature to each of the plurality of nozzles in a predetermined ratio, in which the second temperature is higher than the first temperature. In addition, the adjusting unit supplies the chemical liquid of the second temperature in a higher ratio to the nozzle disposed at the outer circumference side of the substrate than to the nozzle disposed at the center side of the substrate. Each of the nozzles supplies a chemical liquid in which the supplied chemical liquid of the first temperature and the supplied chemical liquid of the second temperature are mixed with each other, to the substrate.

In the above-described substrate processing apparatus, the adjusting unit includes: a first inlet configured to allow inflow of the chemical liquid of the first temperature therethrough; a second inlet configured to allow inflow of the chemical liquid of the second temperature therethrough; a plurality of first supply ports having different diameters and communicating with the plurality of nozzles, respectively, in which the plurality of first supply ports is configured to supply the chemical liquid of the first temperature flowing therein from the first inlet; and a plurality of second supply ports having different diameters and communicating with the plurality of nozzles, respectively, in which the plurality of second supply ports is configured to supply the chemical liquid of the second temperature flowing therein from the second inlet. The plurality of first supply ports is formed such that a first supply port nearer to the center of the substrate has a larger diameter and the plurality of second supply ports is formed such that a second supply port nearer to the outer circumference of the substrate has a larger diameter.

In the above-described substrate processing apparatus, the adjusting unit further includes: a body having an internal space extending in a direction in which the nozzles are arranged, the nozzles being connected to a lower portion of the body; and a partition member configured to partition the internal space of the body into a first space and a second space which are adjacent to each other at left and right sides when viewed in the direction where the nozzles are arranged. The plurality of first supply ports is formed in a lower portion of the first space, the plurality of second supply ports is formed in a lower portion of the second space, the chemical liquid of the first temperature flowing in from the first inlet is supplied to the plurality of nozzles through the first space and the first supply ports, and the chemical liquid of the second temperature flowing in from the second inlet is supplied to the plurality of nozzles through the second space and the second supply ports.

In the above-described substrate processing apparatus, the first inlet is formed in one of a sidewall positioned at the center side of the substrate and a sidewall positioned at the outer circumference side of the substrate, in the body, and the second inlet is formed in the other sidewall.

In the above-described substrate processing apparatus, the first inlet is formed in the sidewall positioned at the outer circumference side of the substrate, and the second inlet is formed in the sidewall positioned at the center side of the substrate.

In the above-described substrate processing apparatus, the partition member is disposed such that the first space has a narrowest width at a side of a first supply port having a smallest diameter among the first supply ports and the second space has a narrowest width at a side of a second supply port having a smallest diameter among the second supply ports.

In the above-described processing apparatus, the lower portion of the body positioned at the first space side is inclined such that a height thereof is reduced toward the first supply port having the smallest diameter from a first supply port having a largest diameter, and the lower portion of the body positioned at the second space side is inclined such that a height thereof is reduced toward a second supply port having a smallest diameter from a second supply port having a largest diameter.

In the above-described processing apparatus, each of the nozzles has a mortar shape with a width being gradually reduced toward an ejecting port.

In the above-described processing apparatus, the adjusting unit includes: a first piping portion including branch pipes and supplied with the chemical liquid of the first temperature from a supply source, the number of the branch pipes being equal to or larger than the number of nozzles; a second piping portion including branch pipes and supplied with the chemical liquid of the second temperature from a supply source, the number of branch pipes being equal to or larger than the number of the nozzles; a plurality of connection portions that connects the branch pipes of the first piping portion and the branch pipes of the second piping portion, respectively; a plurality of third piping portions that connects the plurality of connection portions and the plurality of nozzles, respectively; a plurality of first flow rate adjusting units which is provided in the plurality of branch pipes of the first piping portion, respectively, to adjust a flow rate of the chemical liquid of the first temperature; and a plurality of second flow rate adjusting units which is provided in the plurality of branch pipes of the second piping portion, respectively, to adjust a flow rate of the chemical liquid of the second temperature. The plurality of first flow rate adjusting units is configured such that a first flow rate adjusting unit corresponding to a nozzle nearer to the center of the substrate supplies a higher flow rate of the chemical liquid of the first temperature to a downstream side, and the plurality of second flow rate adjusting units is configured such that a second flow rate adjusting unit corresponding to a nozzle nearer to the outer circumference of the substrate supplies a higher flow rate of the chemical liquid of the second temperature to a downstream side.

A liquid supply apparatus according to another aspect of the present disclosure includes: a plurality of nozzles configured to supply a chemical liquid to a substrate; and an adjusting unit configured to supply a chemical liquid of a first temperature and a chemical liquid of a second temperature to each of the plurality of nozzles in a predetermined ratio, in which the second temperature is higher than the first temperature. The adjusting unit includes: a first inlet configured to allow inflow of the chemical liquid of the first temperature therethrough; a second inlet configured to allow inflow of the chemical liquid of the second temperature therethrough; a plurality of first supply ports having different diameters and communicating with the plurality of nozzles, respectively, in which the plurality of first supply ports is configured to supply the chemical liquid of the first temperature flowing in from the first inlet; and a plurality of second supply ports having different diameters and communicating with the plurality of nozzles, respectively, in which the plurality of second supply ports is configured to supply the chemical liquid of the second temperature flowing in from the second inlet. The plurality of first supply ports is formed such that a first supply port nearer to the center of the substrate when supplying the chemical liquid to the substrate has a larger diameter, and the plurality of second supply ports is formed such that a second supply port nearer to the outer circumference of the substrate when supplying the chemical liquid to the substrate has a larger diameter.

According to exemplary embodiments, a temperature of a chemical liquid at an outer circumference of a substrate is suppressed from being reduced so that an in-plane uniformity in processing the substrate can be enhanced.

Hereinafter, exemplary embodiments of a substrate processing apparatus and a liquid supply apparatus disclosed herein will be described in detail with reference to the accompanying drawings. However, the present disclosure is not limited by the exemplary embodiments described below.

### First Exemplary Embodiment

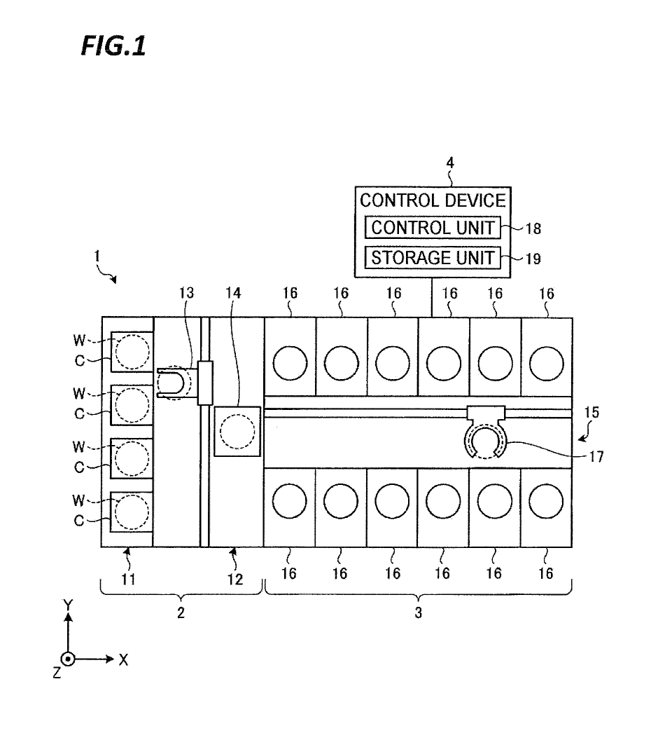

FIG. 1 is a view illustrating a schematic configuration of a substrate processing system according to an exemplary embodiment. Hereinafter, an X axis, a Y axis, and a Z axis which are orthogonal to each other will be defined in order to clarify a positional relationship, and a positive direction of the Z axis will be assumed as a vertical upward direction.

As illustrated in FIG. 1, a substrate processing system 1 is provided with a carry-in/carry-out station 2, and a processing station 3. The carry-in/carry-out station 2 and the processing station 3 are provided to be adjacent to each other.

The carry-in/carry-out station 2 is provided with a carrier mounting section 11 and a conveyance section 12. A plurality of carriers C is mounted in the carrier mounting section 11, in which a plurality of substrates (in a first exemplary embodiment, semiconductor wafers) (hereinafter, referred to as “wafers W”) is horizontally accommodated in each of the plurality of carriers C.

The conveyance section 12 is provided adjacent to the carrier mounting section 11, and includes a substrate conveyance device 13 and a delivery unit 14 therein. The substrate conveyance device 13 is provided with a wafer holding mechanism configured to hold a wafer W. In addition, the substrate conveyance device 13 is capable of being moved horizontally and vertically and turned about a vertical axis so as to perform the conveyance of the wafer W between the carriers C and the delivery unit 14 using the wafer holding mechanism.

The processing station 3 is provided adjacent to the conveyance section 12. The processing station 3 is provided with a conveyance section 15, and a plurality of processing units 16. The plurality of processing units 16 is provided to be aligned at both sides of the conveyance section 15.

The conveyance section 15 includes a substrate conveyance device 17 therein. The substrate conveyance device 17 is provided with a wafer holding mechanism configured to hold the wafer W. In addition, the substrate conveyance device 17 is capable of being moved horizontally and vertically and turned above a vertical axis so as to perform conveyance of the wafer W between the delivery unit 14 and the processing unit 16, using the wafer holding mechanism.

The processing unit 16 performs a predetermined substrate processing on the wafer W conveyed by the substrate conveyance device 17.

In addition, the substrate processing system 1 is provided with a control device 4. The control device 4 is, for example, a computer, and is provided with a control unit 18 and a storage unit 19. The storage unit 19 stores a program that controls various processings executed in the substrate processing system 1. The control unit 18 reads and executes the program stored in the storage unit 19 so as to control the operation of the substrate processing system 1.

The program may be recorded in a computer-readable storage medium and installed in the storage unit 19 of the control device 4 from the storage medium. The computer-readable storage medium may be, for example, a hard disc (RD), a flexible disc (FD), a compact disc (CD), a magneto-optical disc (MO), or a memory card.

In the substrate processing system 1 configured as described above, the substrate conveyance device 13 of the carry-in/carry-out station 2 unloads a wafer W from a carrier C mounted in the carrier mounting section 11 and disposes the unloaded wafer on the delivery unit 14. The wafer W disposed on the wafer delivery unit 14 is unloaded from the delivery unit 14 and carried into the processing unit 16 by the substrate conveyance device 17 of the processing station 3.

After being processed by the processing unit 16, the wafer W carried into the processing unit 16 is carried out from the processing unit 16 and then disposed on the delivery unit 14 by the substrate conveyance device17. In addition, after being processed, the wafer W is disposed on the delivery unit 14 and returned to the carrier C of the carrier mounting section 11 by the substrate conveyance device 13.

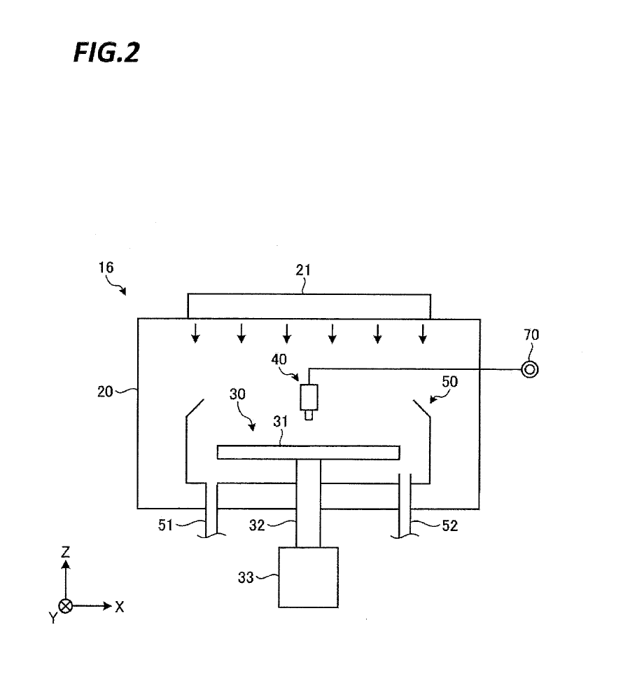

Next, a schematic configuration of the processing unit 16 will be described with reference to FIG. 2. FIG. 2 is a view illustrating the schematic configuration of the processing unit 16.

As illustrated in FIG. 2, the processing unit 16 is provided with a chamber 20, a substrate holding mechanism 30, a processing fluid supply unit 40, and a recovery cup 50.

The chamber 20 accommodates a substrate holding mechanism 30, a processing fluid supply unit 40, and a recovery cup 50. A fan filter unit (FFU) 21 is provided on a ceiling portion of the chamber 20. The FFU 21 forms down-flow within the chamber 20.

The substrate holding mechanism 30 is provided with a holding unit 31, a support unit 32, and a driving unit 33. The holding unit 31 holds a wafer W horizontally. The support unit 32 is a member extending vertically, in which a base end of the support unit 32 is rotatably supported by the driving unit 33, and the holding unit 31 is supported horizontally by a tip end of the support unit 32. The driving unit 33 rotates the support unit 32 around a vertical axis. When the substrate holding mechanism 30 rotates the support unit 32 using the driving unit 33, the holding unit 31 supported by the support unit 32 is rotated, and therefore, the wafer W held by the holding unit 31 is rotated.

The processing fluid supply unit 40 supplies a processing fluid to the wafer W. The processing fluid supply unit 40 is connected to a processing fluid supply source 70.

The recovery cup 50 is disposed to surround the holding unit 31 to collect the processing liquid scattered from the wafer W due to the rotation of the holding unit 31. A liquid discharge port 51 is formed in the bottom portion of the recovery cup 50, and the processing liquid collected by the recovery cup 50 is discharged to the outside of the processing unit 16 from the liquid discharge port 51. In addition, a gas discharge port 52 is formed in the bottom portion of the recovery cup 50 to discharge a gas supplied from the FFU 21 to the outside of the processing unit 16.

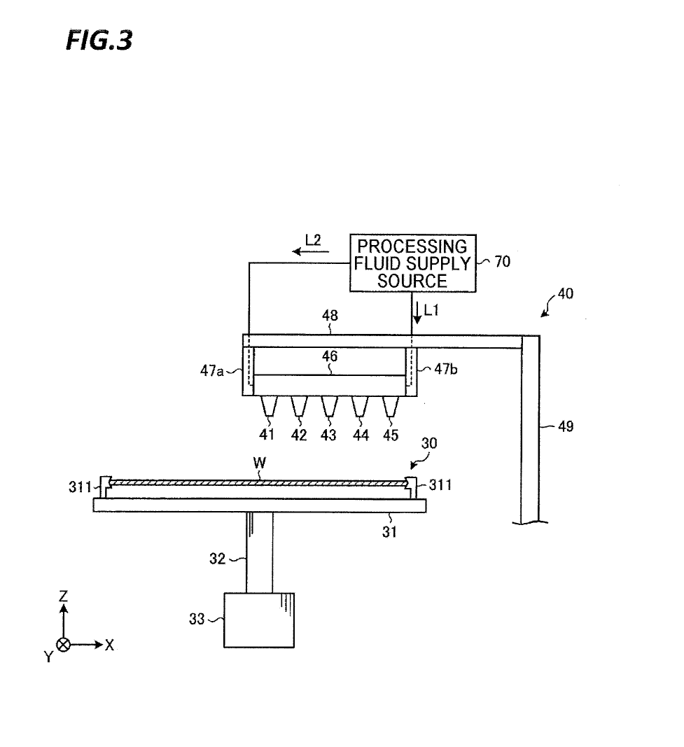

Next, a configuration of the substrate holding mechanism 30 and the processing fluid supply unit 40 will be described with reference to FIG. 3. FIG. 3 is a view illustrating a configuration of the substrate holding mechanism 30 and the processing fluid supply unit 40. The processing unit 16 (corresponding to an example of the “substrate processing apparatus”) supplies an etching liquid such as, for example, HF, to the wafer W so as to etch and remove a film formed on the wafer W.

As illustrated in FIG. 3, on the top surface of the holding unit 31 provided in the substrate holding mechanism 30, holding members 311 are provided to hold the wafer W from a side of the wafer W. The wafer W is horizontally held to be slightly spaced apart from the top surface of the holding unit 31 by the holding members 311. The configuration of the substrate holding mechanism 30 is not limited to that illustrated in the drawing.

The processing fluid supply unit 40 supplies the etching liquid to the wafer W held on the substrate holding mechanism 30. The processing fluid supply unit 40 is provided with a plurality of nozzles 41 to 45, an adjusting unit 46, support units 47a and 47b, an arm 48, and a turning/lifting mechanism 49.

The plurality of nozzles 41 to 45 is disposed to be arranged in a diametric direction of the wafer W. The adjusting unit 46 is an elongated member extending in the arranging direction of the nozzles 41 to 45, and supported on the arm 48 through the support units 47a and 47b. The nozzles 41 to 45 are provided on the bottom of the adjusting unit 46. The arm 48 supports the nozzles 41 to 45 horizontally through the adjusting unit 46 and the support units 47a and 47b. A turning/lifting mechanism 49 turns and lifts the arm 48.

An etching liquid having a first temperature (hereinafter, referred to as a “first etching liquid L1”) and an etching liquid having a second temperature higher than the first temperature (hereinafter, referred to as a “second etching liquid L2”) are supplied to the adjusting unit 46 from the processing fluid supply source 70. The first etching liquid L1 is supplied to an end of the adjusting unit 46 positioned at the outer circumference side of the wafer W through the support unit 47b, and the second etching liquid L2 is supplied to an end of the adjusting unit 46 positioned at the center side of the wafer W through the support unit 47a. In the present exemplary embodiment, the support unit 47a and the support unit 47b are hollow, and the etching liquids pass through the inside thereof. However, without being limited thereto, a pipe for the first etching liquid L1 and a pipe for the second etching liquid L2 may be provided outside of the support unit 47a and the support unit 47b so as to connect the arm 48 and the adjusting unit 46.

In addition, the adjusting unit 46 supplies the first etching liquid L1 and the second etching liquid L2 supplied from the processing fluid supply source 70 to the nozzles 41 to 45 with different ratios for respective nozzles 41 to 45.

Specifically, the adjusting unit 46 supplies the first etching liquid L1 and the etching liquid L2 to the nozzles 41 to 45 such that the ratio of the second etching liquid L2 in relation to the first etching liquid L1 becomes higher at a nozzle positioned nearer to the outer circumference of the wafer W among the nozzles 41 to 45.

As a result, the temperature of the etching liquid supplied from the adjusting unit 46 to each of the nozzles 41 to 45 becomes lowest at the nozzle 41 positioned nearest to the center side of the wafer W, and becomes highest at the nozzle 45 positioned nearest to the outer circumference side of the wafer W.

As described above, the processing unit 16 according to the present exemplary embodiment is configured such that the temperature of the etching liquid supplied to the wafer W becomes higher at a nozzle nearer to the outer circumference side of the wafer W among the nozzles 41 to 45. As a result, the processing unit 16 may enhance an in-plane temperature uniformity of the etching liquid on the wafer W, and hence, enhance an in-plane uniformity of the etching processing.

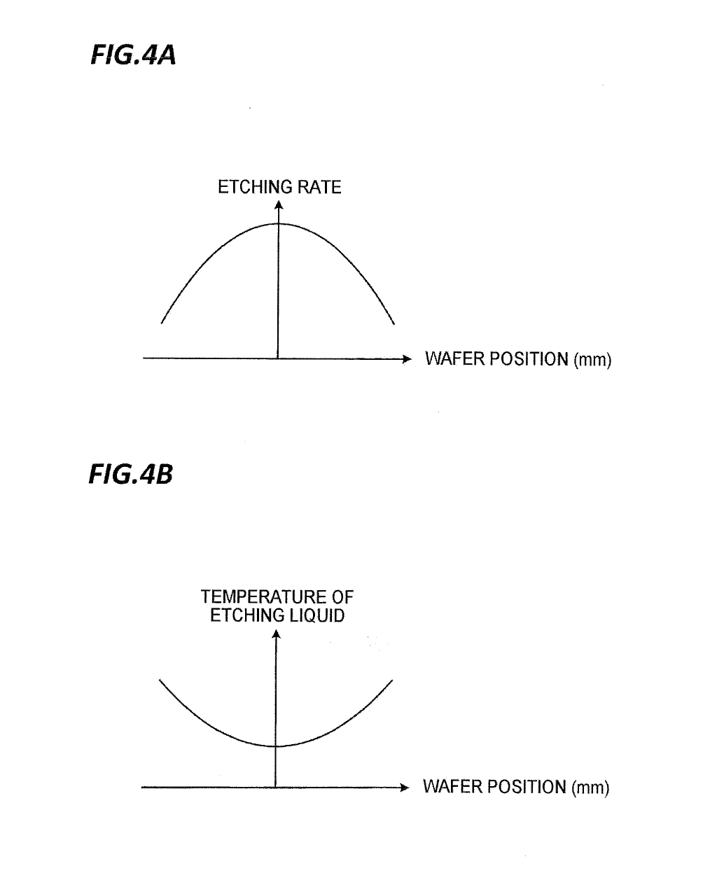

This will be described in comparison to a case in which an etching liquid is supplied to a center of a wafer W from a single nozzle. FIG. 4A is a view illustrating a relationship between a position on a wafer and an etching rate in a case where an etching liquid is supplied to a center of a wafer W while the wafer W is rotating. In addition, FIG. 4B is a view illustrating a relationship between a temperature of an etching liquid and a position on a wafer in the present exemplary embodiment.

As illustrated in FIG. 4A, when the etching liquid is supplied to the center of the wafer W from a single nozzle while the wafer W is rotating, the etching rate is highest at the center of the wafer W and is gradually decreased toward the outer circumference of the wafer W. This is because the temperature of the etching liquid is reduced until the etching liquid reaches the outer circumference of the wafer W after supplied to the center of the wafer W.

Thus, in the method of supplying the etching liquid to the center of the wafer W from the single nozzle while the wafer is rotating, there is a room for additional improvement in improving an etching uniformity from the fact that the in-plane temperature of the wafer W may be easily changed.

Accordingly, as illustrated in FIG. 4B, the processing unit 16 according to the present exemplary embodiment is configured such that, among the nozzles 41 to 45, a nozzle nearer to the outer circumference of the wafer W supplies an etching liquid having a higher temperature. As such, the in-plane temperature uniformity of the etching liquid on the wafer W can be enhanced and thus, the in-plane uniformity of the etching processing can be enhanced.

The temperature of the etching liquid supplied from each of the nozzles 41 to 45 may be determined based on, for example, an in-plane temperature distribution on a wafer W in a case where the etching liquid of the same temperature was supplied from each of the nozzles. For example, assuming that the temperature of the outer circumference of the wafer W was X−α° C. when each of the nozzles 41 to 45 supplied the etching liquid at X° C., the processing unit 16 may set the temperature of the etching liquid supplied from the nozzle 45 positioned at the outer circumference of the wafer W to X+α° C.

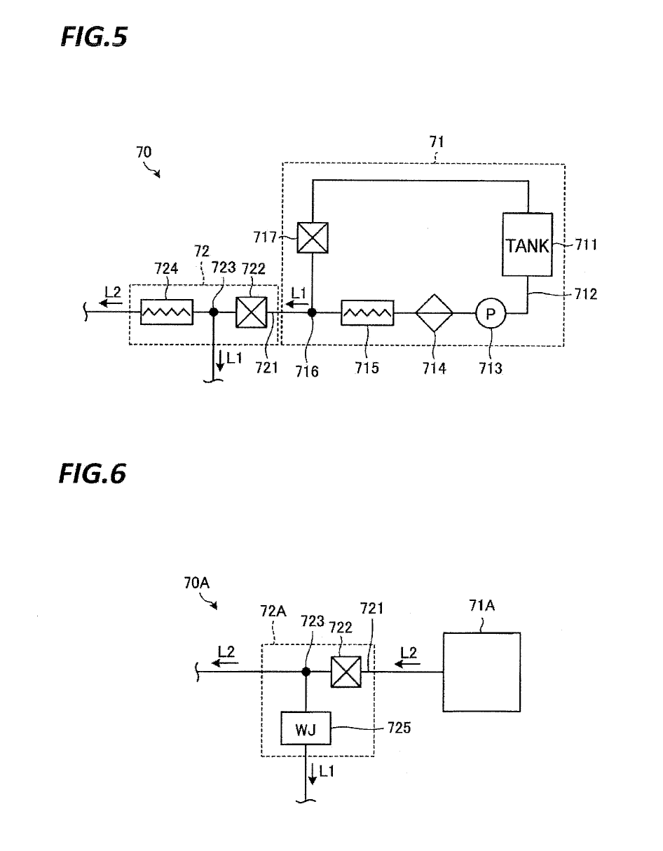

Next, a configuration of a processing fluid supply source 70 will be described with reference to FIG. 5. FIG. 5 is a view illustrating a configuration of the processing fluid supply source 70.

As illustrated in FIG. 5, the processing fluid supply source 70 is provided with a circulation line 71, and an ejection line 72. The circulation line 71 is provided with a tank 711, a piping portion 712, a pump 713, a filter 714, a heating unit 715, a branching portion 716, and a valve 717.

The tank 711 stores an etching liquid. The piping portion 712 is connected to the tank 711 at opposite ends thereof so as to form a route of circulating the etching liquid. The piping portion 712 is provided with the pump 713, the filter 714, the heating unit 715, the branching portion 716, and the valve 717 in this order from the upstream side.

The pump 713 pumps the etching liquid stored in the tank 711 to the downstream side. The filter 714 removes foreign matters in the etching liquid. The heating unit 715 is, for example, a heater, and raises the temperature of the etching liquid supplied from the upstream side to a first temperature. The valve 717 opens/closes the piping portion 712.

Meanwhile, the ejection line 72 is provided with a piping portion 721, a valve 722, a branching portion 723, and a heating unit 724. The piping portion 721 is connected to the branching portion 716 of the circulation line 71. Such a piping portion 721 is provided with the valve 722, the branching portion 723, and the heating unit 724 in this order from the upstream side. The valve 722 opens/closes the piping portion 721.

The branching portion 723 supplies the etching liquid supplied from the circulation line 71, i.e. the first etching liquid L1 to each of the heating unit 724 and the processing fluid supply unit 40 (see, e.g., FIG. 3). The heating unit 724 is, for example, a heater. The heating unit 724 raises the temperature of the first etching liquid L1 supplied from the branching portion 723 to a second temperature and supplies a second etching liquid L2, which is the temperature-raised etching liquid, to the processing fluid supply unit 40.

The processing fluid supply source 70 raises the temperature of the first etching liquid L1 supplied from the circulation line 71 to the second temperature in the ejection line 72 as described above so that the etching liquids L1 and L2 adjusted to two system temperatures can be supplied to the processing fluid supply unit 40.

For example, with respect to the substrate processing system 1, one circulation line 71 may be provided and the ejection line 72 may be provided in each processing unit 16. That is, a plurality of ejection lines 72 may be connected to the branching portion 716 of the circulation line 71. With this configuration, it is possible to suppress the substrate processing system 1 from being enlarged.

In the above-described example, the first etching liquid L1 is supplied from the circulation line 71 to the ejection line 72, and the temperature of the first etching liquid L1 in the ejection line 72 is raised to the second temperature. However, the configuration of the processing fluid supply source 70 is not limited to the above-described example. Thus, another exemplary configuration of the processing fluid supply source 70 will be described with reference to FIG. 6. FIG. 6 is a view illustrating another configuration of the processing fluid supply source.

As illustrated in FIG. 6, a processing fluid supply source 70A is provided with a circulation line 71A, and an ejection line 72A. The circulation line 71A has the same configuration as the circulation line 71. Such a circulation line 71A raises the temperature of the etching liquid to the second temperature in the heating unit 715, and supplies the second etching liquid L2 to the ejection line 72A.

The ejection line 72A is provided with a cooling unit 725 instead of the ejection line 72 provided in the heating unit 724. The cooling unit 725 is, for example, a water jacket. The cooling unit 725 cools the second etching liquid L2 supplied from the branching portion 723 to a first temperature, and supplies the first etching liquid L1 which is the cooled etching liquid to the processing fluid supply unit 40.

As described above, the processing fluid supply source 70A may be configured to supply the second etching liquid L2 from the circulation line 71A to the ejection line 72A, and cool the temperature of the second etching liquid L2 to the first temperature ejection line 72A.

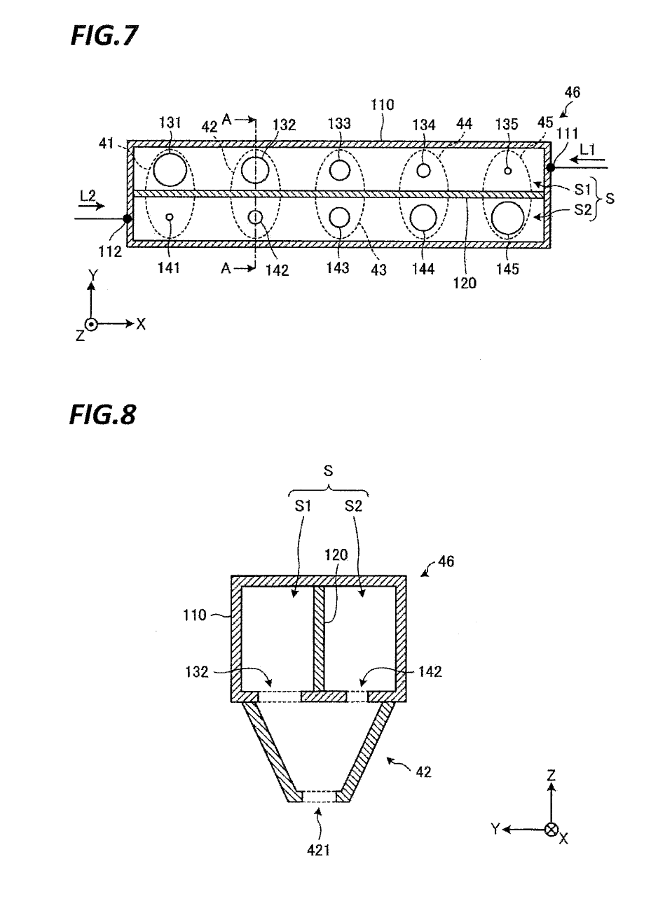

Next, a configuration of an adjusting unit 46 provided in the processing fluid supply unit 40 will be described with reference to FIGS. 7 and 8. FIG. 7 is a schematic cross-sectional plan view illustrating the adjusting unit 46. In addition, FIG. 8 is a cross-sectional view taken along line A-A in FIG. 7.

As illustrated in FIG. 7, the adjusting unit 46 is provided with a body 110, a partition member 120, first supply ports 131 to 135, and second supply ports 141 to 145.

The body 110 has an internal surface S extending in the arranging direction of the nozzles 41 to 45. The nozzles 41 to 45 are connected to a lower portion of the body 110.

The partition member 120 partitions the internal space S of the body. Specifically, the partition member 120 has opposite ends which are fixed to a sidewall positioned at the center side of the wafer W and a sidewall positioned at the outer circumference side in the body 110 of the wafer W, respectively. The internal space S of the body 110 are partitioned by the partition member 120 into two spaces adjacent to each other when viewed in the direction of arranging the nozzles 41 to 45. Hereinafter, in the two spaces partitioned by the partition member 120, with respect to the X axis, a left space in the positive direction is referred to as a first space S1 and a right space is referred to as a second space S2.

On a sidewall of the body 110 at the first space S1 side, a first inlet 111 is formed to allow the first etching liquid L1 to flow into the first space S1, and on a sidewall at the second space S2, a second inlet 112 is formed to allow the second etching liquid L2 to flow into the second space S2. Accordingly, in the first etching liquid L1 and the second etching liquid L2 supplied from the processing fluid supply source 70, the first etching liquid L1 is supplied to the first space S1, and the second etching liquid L2 is supplied to the second space S2.

In addition, the first inlet 111 is formed on a sidewall of the body 110 at the wafer W outer circumference side, and the second inlet 112 is formed on a sidewall positioned at the center side of the wafer W. When the first inlet 111 is formed on one sidewall of the body 110 and the second inlet 112 is formed on the other sidewall, thermal interference between the first etching liquid L1 and the second etching liquid L2 which have different temperatures can be suppressed. In addition, the ejection of the etching liquid from each of the nozzles 41 to 45 may be timed.

The first supply ports 131 to 135 and the second supply ports 141 to 145 are circular openings formed in the lower portion of the body 110. Specifically, the first supply ports 131 to 135 are formed in the lower portions at the first space S1 side in the body 110, and the second supply ports 141 to 145 are formed in the lower portions at the second space S2 side in the body 110.

The first supply port 131 and the second supply port 141 are formed at a position overlapping with the nozzle 41 when viewed from the upper side of the body 110. Similarly, the first supply port 132 and the second supply port142, the first supply port 133 and the second supply port 143, the first supply port 134 and the second supply port 144, and the first supply port 135 and the second supply port 145 are formed at positions which overlap with the nozzles 42 to 45, respectively.

As a result, the nozzle 41 communicates with the first space S1 of the body 110 through the first supply port 131, and communicates with the second space S2 through the second supply port 141. Similarly, the nozzles 42 to 45 communicate with the first space S1 of the body 110 through the first supply ports 132 to 135, and communicate with the second space S2 through the second supply ports 142 to 145.

As described above, the nozzles 41 to 45 communicate with the first space S1 and the second space S2 through the first supply ports 131 to 135 and the second supply ports 141 to 145, respectively. For example, as illustrated in FIG. 8, the nozzle 42 communicates with the first space S1 through the first supply port 132 and communicates with the second space S2 through the second supply port 142. Accordingly, the nozzle 42 is supplied with the first etching liquid L1 through the first supply port 132, and with the second etching liquid L2 through the second supply port 142.

As described above, because the nozzles 41 to 45 are supplied with the first etching liquid L1 and the second etching liquid L2, the first etching liquid L1 and the second etching liquid L2 are mixed and ejected from the nozzles 41 to 45.

In addition, as illustrated in FIG. 7, the first supply ports 131 to 135 are formed such that a first supply port nearer to the center of the wafer W has a lager diameter, and the second supply ports 141 to 145 are formed such that a second supply port nearer to the outer circumference of the wafer W has a larger diameter. For this reason, a nozzle nearer to the center of the wafer W (e.g., the nozzle 41) is supplied with more first etching liquid L1 than the second etching liquid L2, and a nozzle nearer to the outer circumference wafer W (e.g., the nozzle 45) is supplied with the more second etching liquid L2 than the first etching liquid L1. Thus, among the nozzles 41 to 45, a nozzle nearer to the outer circumference of the wafer W ejects the etching liquid at a higher temperature.

As described above, in the processing unit 16 according to the present exemplary embodiment, the diameters of the first supply ports 131 to 135 and the second supply ports 141 to 145 are set to be different from each other so that the flow rates of the first etching liquids L1 and the second etching liquids L2 supplied to respective nozzles 41 to 45 are different from each other. By this, etching liquids of a plurality of temperatures may be formed from the etching liquids (the first etching liquid L1 and the second etching liquid L2) of two temperatures. Thus, it is possible to simplify the configuration of the apparatus as compared to, for example, a case in which a temperature adjusting mechanism of the etching liquid is provided in each of the nozzles 41 to 45.

In addition, the diameter of the first supply port 131 and the diameter of the second supply port 145 are equal to each other, the diameter of the first supply port 132 and the diameter of the second supply port 144 are equal to each other, and the diameter of the first supply port 133 and the diameter of the second supply port 143 are equal to each other. Accordingly, it is possible to adjust the flow rate of the etching liquid supplied to each of the nozzles (41 to 45).

In addition, the first inlet 111 is formed on the sidewall at the side where the first supply port 135 with the smallest diameter (hereinafter, referred to as a “smallest supply port 135”) is formed among the first supply ports 131 to 135, and the second inlet 112 is formed on the sidewall at the side where the second supply port 141 with the smallest diameter (hereinafter, referred to as a “smallest supply port 141”) is formed among the second supply ports 141 to 145.

As described above, in the processing unit 16, the first inlet 111 and the second inlet 112 are formed at the sides where the smallest first supply port 135 and the smallest second supply port 141 are formed, respectively. By this, it is possible to suppress a power loss of the first etching liquid L1 and the second etching liquid L2 in the first space S1 and the second space S2 so that the etching liquid flows into each of the supply ports at a substantially equal pressure. Accordingly, the flow rate of the etching liquid supplied to each of the nozzles 41 to 45 may be further adjusted.

In addition, the nozzle 42 has a mortar shape with the width being gradually reduced from the first supply port 132 and the second supply port 142 to the ejecting port 421 (see, e.g., FIG. 8). Further, the other nozzles 41 and 43 to 45 have the same configuration as the nozzle 42. Accordingly, as compared to, for example, a cylindrical nozzle, the first etching liquid L1 and the second etching liquid L2 may be easily mixed in the nozzles 41 to 45 so that an etching liquid having a desired temperature can be stably ejected from each of the nozzles41 to 45.

In addition, the first supply ports 131 to 135 and the second supply ports 141 to 145 may be opened to be oblique toward each other. With this configuration, the first etching liquid L1 and the second etching liquid L2 may be mixed in the nozzles 41 to 45 more easily so that the temperature of the etching liquid ejected from each of the nozzles 41 to 45 can be further stabilized. Specifically, the first supply ports 131 to 135 and the second supply ports 141 to 145 may be opened in a direction in which the etching liquids supplied from the first supply ports 131 to 135 and the second supply ports 141 to 145 collide with each other in the spaces within the nozzles 41 to 45. On the contrary, the first supply ports 131 to 135 and the second supply ports 141 to 145 may be opened in a direction in which each etching liquid directly collides with the inner wall of each of the nozzles 41 to 45. In such a case, an etching liquid at one side may collide with the inner wall of each of the nozzles 41 to 45 and may be transferred along the surface of the inner wall to be mixed with another etching liquid transferred from the other side in the same manner.

In addition, each of the nozzles 41 to 45 may include a helical groove therein. By this, vortices may be easily generated in each of the nozzles 41 to 45 so that the first etching liquid L1 and the second etching liquid L2 may be more easily mixed in each of the nozzles 41 to 45.

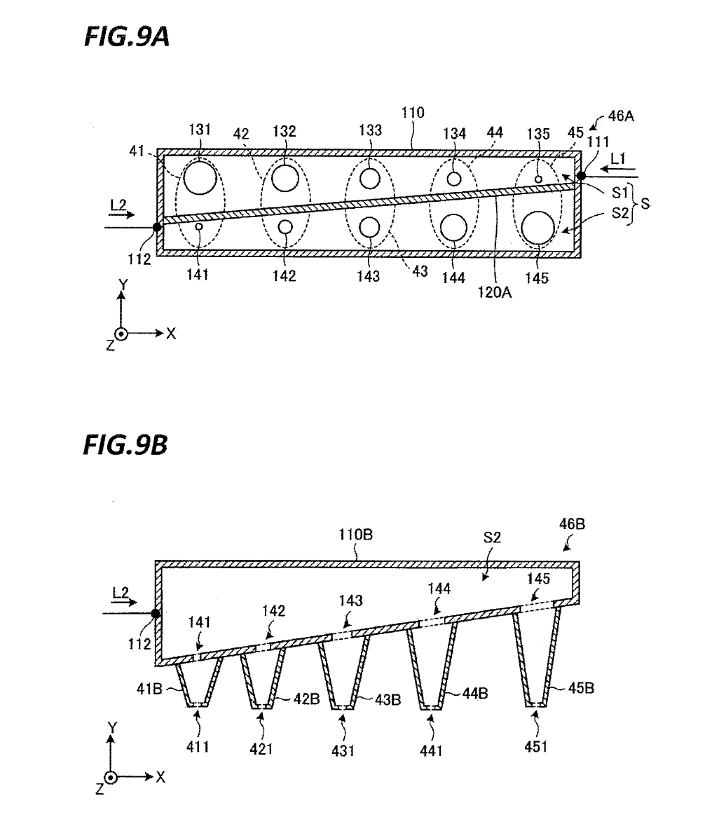

In addition, the configuration of the adjusting unit 46 may be designed to suppress a pressure loss of the first etching liquid L1 and the second etching liquid L2 within the first space S1 and the second space S2. This point will be described with reference to FIGS. 9A and 9B. FIG. 9A and FIG. 9B are views illustrating another configuration of the adjusting unit.

As illustrated in FIG. 9A, the adjusting unit 46A is provided with a partition member 120A. The partition member 120A is disposed in the body 110 such that the spaces positioned at the smallest first supply port 135 and smallest second supply port 141 sides are narrowest. By this, the width of the flow path of the first space S1 is increased toward the largest first supply port 131 side, and decreased toward the smallest first supply port 135 side, and the width of the flow path of the second space S2 is also increased toward the largest second supply port 145 side and decreased toward the smallest second supply port 141 side. For this reason, a pressure loss of the first etching liquid L1 and the second etching liquid L2 in the first space S1 and the second space S2 may be suppressed so that the etching liquid may flow into each of the supply ports 131 to 135 and 141 to 145 at a substantially equal pressure.

In addition, as illustrated in FIG. 9B, the adjusting unit 46B is provided with a body 110B. The second space S2 side lower portion of the body 110B is inclined such that the height of the lower portion is reduced from the largest second supply port 145 toward the smallest second supply port 141. Similarly, although not illustrated here, the lower portion of the body 110B positioned at the first space side S1 is also inclined such that the height of the lower portion is reduced from the largest first supply port 131 toward the smallest first supply port 135.

By this, the height of the flow path in the first space S1 is increased toward the largest first supply port 131 side, and decreased toward the smallest first supply port 135 side, and the height of the flow path of the second space S2 is also increased toward the second supply port 145 side and decreased toward the smallest second supply port 141. Thus, a pressure loss of the first etching liquid. L1 and the second etching liquid L2 in the first space S1 and the second space S2 may be suppressed so that the etching liquids may flow into respective supply ports 131 to 135 and 141 to 145 at a substantially equal pressure.

As described above, when the internal space S of the body 110 is partitioned such that, among the first supply ports 131 to 135 and the second supply ports 141 to 145, the spaces positioned at the largest first supply port 131 and the largest second supply port 145 sides become wider, the pressure loss of the first etching liquid L1 and the second etching liquid L2 in the first space S1 and the second space S2 may be suppressed so that the etching liquids may flow into respective supply ports 131 to 135 and 141 to 145 at a substantially equal pressure.

Although FIG. 9B illustrates an example in which the nozzles 41B to 45B are formed to have different shapes, respectively, in order to adjust height positions of the ejecting ports 411, 421, 431, 441, and 451, it is not necessarily required to adjust the heights of the ejecting ports 411, 421, 431, 441, and 451. That is, the nozzles 41B to 45B may have the same shape.

As described above, the processing unit 16 according to the first exemplary embodiment (corresponding to an example of “substrate processing apparatus”) is provided with a substrate holding mechanism 30 (an example of a “holing mechanism”), a processing fluid supply unit 40, and a processing fluid supply source 70 or 70A (an example of a “supply source”). The substrate holding mechanism 30 rotatably holds a wafer W. The processing fluid supply unit 40 supplies an etching liquid which is a chemical liquid to the wafer W held by the substrate holding mechanism 30. The processing fluid supply sources 70 and 70A supply an etching liquid of a first temperature and an etching liquid of a second temperature which is higher than the first temperature to the processing fluid supply unit 40.

In addition, the processing fluid supply unit 40 is provided with a plurality of nozzles 41 to 45, and an adjusting units 46, 46A, or 46B. The plurality of nozzles 41 to 45 are disposed to be arranged in a diametric direction of the wafer W. The adjusting unit 46, 46A or 46B supplies the etching liquid of the first temperature and the etching liquid of the second temperature supplied from the processing fluid supply source 70 or 70A to each of the nozzles 41 to 45 at a predetermined ratio. In addition, the adjusting unit 46, 46A or 46B supplies the etching liquid of the second temperature to the nozzle disposed at the outer circumference side of the wafer W (e.g., the nozzle 45) in a higher ratio than the nozzle disposed at the center side of the wafer W (e.g., the nozzle 41).

Accordingly, the processing unit 16 according to the first exemplary embodiment may enhance an etching uniformity.

In addition, in the above described first exemplary embodiment, an example in which the first etching liquid and the second etching liquid flow into the first space S1 and the second space S2 from the first inlet 111 and the second inlet 112 formed on both sidewalls of the body 110 has been described. However, the inflow positions of the first etching liquid and the second etching liquid are not limited to the above example. For example, the first inlet 111 may be formed on the sidewall positioned at the largest first supply port 131 side and the second inlet 112 may be formed on the sidewall positioned at the largest second supply port 145 side. In addition, both the first inlet 111 and the second inlet 112 may be formed on any one of the sidewalls in the body 110. In addition, the first inlet 111 and the second inlet 112 may be formed on a top portion (ceiling portion) rather than on the sidewalls of the body 110. Further, the body 110 is not an essential component and the plurality of supply ports may be directly formed on top ends of pipings that supply the first etching liquid and the second etching liquid.

### Second Exemplary Embodiment

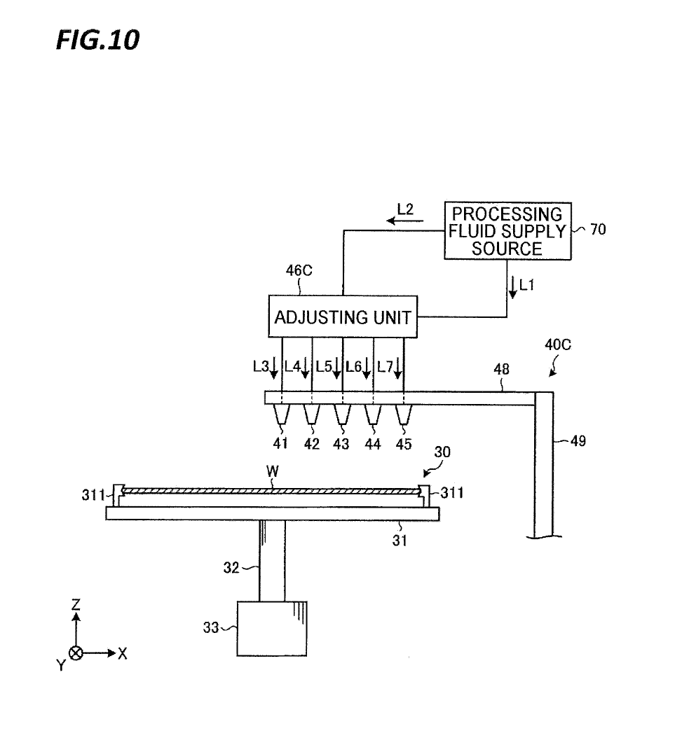

Next, a configuration of a processing fluid supply unit according to a second exemplary embodiment will be described with reference to FIG. 10. FIG. 10 is a view illustrating a configuration of a substrate holding mechanism and a processing fluid supply unit according to a second exemplary embodiment. In the following description, the components which are the same as the components already described above will be denoted by the same symbols and overlapping descriptions will be omitted.

As illustrated in FIG. 10, a processing fluid supply unit 40C according to a second exemplary embodiment is provided with nozzles 41 to 45, an adjusting unit 46C, an arm 48, and a turning/lifting mechanism 49. The nozzles 41 to 45 are provided on the arm 48.

The adjusting unit 46C mixes a first etching liquid L1 and a second etching liquid L2 supplied from the processing fluid supply source 70 in a mixture ratio according to the nozzles 41 to 45, and supplies mixed etching liquids L3 to L7 to respective nozzles 41 to 45.

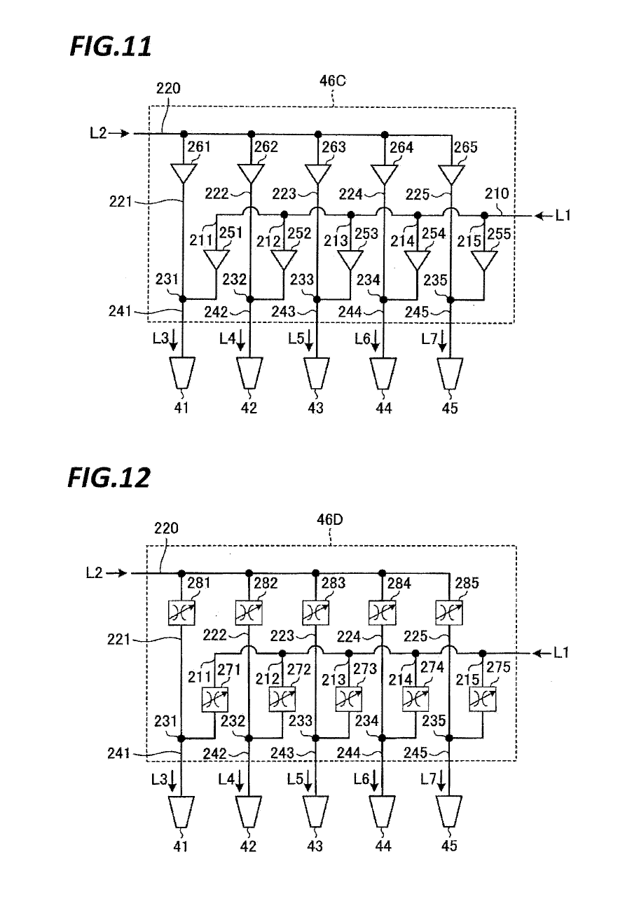

Subsequently, a configuration of the adjusting unit 46C will be described with reference to FIG. 11. FIG. 11 is a view illustrating a configuration of the adjusting unit 46C according to the second exemplary embodiment.

As illustrated in FIG. 11, the adjusting unit 46C is provided with a first piping portion 210, a second piping portion 220, connection portions 231 to 235, third piping portions 241 to 245, first orifices 251 to 255, and second orifices 261 to 265.

The first piping portion 210 includes branch pipes 211 to 215 corresponding to the nozzles 41 to 45, respectively, and is supplied with the first etching liquid L1 from the processing fluid supply source 70. The second piping portion 220 includes branch pipes 221 to 225 corresponding to the nozzles 41 to 45, respectively, and is supplied with the second etching liquid L2 from the processing fluid supply source 70.

The connection portions 231 to 235 connect the branch pipes 211 to 215 of the first piping portion 210 and the branch pipe 221 to 225 of the second piping portion 220, respectively. The first orifices 251 to 255 are provided in the branch pipes 211 to 215 of the first piping portion 210, respectively, to serve as flow rate adjusting units that adjust the flow rate of the first etching liquid L1. In addition, the second orifices 261 to 265 are provided on the branch pipes 221 to 225 of the second piping portion 220 to serve as flow rate adjusting units that adjust the flow rate of the second etching liquid L2.

The adjusting unit 46C is configured as described above, and the first etching liquid L1 and the second etching liquid L2 are subjected to adjustment of flow rate by the first orifices 251 to 255 and the second orifices 261 to 265, respectively, and then mixed in the connection portions 231 to 235 so that etching liquids L3 to L7 are supplied to the nozzles 41 to 45, respectively.

Here, in the adjusting unit 46C according to the second exemplary embodiment, the diameters of the first orifices 251 to 255 and the second orifices 261 to 265 are set to be different from each other so that the temperatures of the etching liquids L3 to L7 supplied to respective nozzles 41 to 45 are different from each other.

Specifically, the first orifices 251 to 255 are formed such that an orifice nearer to the center of a wafer W has a larger diameter, and the second orifices 261 to 265 are formed such that an orifice nearer to an outer circumference of the wafer W has a larger diameter.

Accordingly, among the nozzles 41 to 45, a nozzle nearer to the center of the wafer W is supplied with more first etching liquid L1 than second etching liquid L2 and a nozzle nearer to the outer circumference of the wafer W is supplied with more second etching liquid L2 than first etching liquid L1. As a result, among the nozzles 41 to 45, a nozzle nearer to the outer circumference of the wafer W ejects an etching liquid at a higher temperature.

As described above, in the processing unit 16 according to the second exemplary embodiments, the diameters of the first orifices 251 to 255 and the second orifices 261 to 265 are set to be different from each other so that the flow rates of the first etching liquid L1 and the second etching liquid L2 supplied to each of the nozzles 41 to 45 may be different from each other. In addition, even if, for example, a temperature condition of a substrate is changed, it is possible to respond by replacing each orifice so that etching rates become uniform.

### Third Exemplary Embodiment

Next, a configuration a an adjusting unit according to a third exemplary embodiment will be described with reference to FIG. 12. FIG. 12 is a view illustrating a configuration of an adjusting unit according to a third exemplary embodiment.

As illustrated in FIG. 12, the adjusting unit 46D according to the third exemplary embodiment is provided with first constant pressure valves 271 to 275 and second constant pressure valves 281 to 285, instead of the first orifices 251 to 255 and the second orifices 261 to 265 provided in the adjusting unit 46C according to the second exemplary embodiment. The first constant pressure valves 271 to 275 and the second constant pressure valves 281 to 285 may change the flow rates of the first etching liquid L1 and the second etching liquid L2 flowing at the downstream side unlike the first orifices 251 to 255 and the second orifices 261 to 26.

When the first constant pressure valves 271 to 275 and the second constant pressure valves 281 to 285 which are configured to control a flow rate are used as flow rate adjusting units, it is also possible to respond even if a flow rate of an etching liquid ejected from each of the nozzles 41 to 45 according to, for example, a change of a recipe is changed.

In FIG. 12, the first constant pressure valves 271 to 275 and the second constant pressure valves 281 to 285 are provided to correspond to the nozzles 41 to 45, respectively. However, among the first constant pressure valves 271 to 275 and the second constant pressure valves 281 to 285, the first constant pressure valve 275 and the second constant pressure valve 281 may be omitted. This is also applicable to the first supply port 135 and the second supply port 141 in the first exemplary embodiment and the first orifice 255 and the second orifice 261 in the second exemplary embodiment.

Although each of the above-described exemplary embodiments has been described with reference to a case in which an etching liquid is used as a chemical liquid, the substrate processing apparatus disclosed herein is also applicable to a case where a cleaning liquid, for example, SC1 (a mixture liquid of aqueous ammonia and aqueous hydrogen peroxide) or SC2 (a mixture liquid of an acid such as hydrochloric acid and aqueous hydrogen peroxide) is supplied without being limited to the case where the etching liquid is supplied to a substrate. Further, the substrate processing apparatus is also applicable to a case where a plating solution or a developing solution is supplied. From a different viewpoint, a processing fluid supply unit 40 including nozzles 41 to 45 and an adjusting unit 46, 46b or 46c in each of the above-described exemplary embodiments may be used as one liquid supply apparatus having the above-described characteristic functions in an apparatus that performs various processing such as, for example, an etching processing and a cleaning processing.

From the foregoing, it will be appreciated that various exemplary embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. A substrate processing apparatus comprising:
a holding mechanism configured to rotatably hold a substrate;
a plurality of nozzles disposed to be arranged in a diametric direction of the substrate held by the holding mechanism and configured to supply a chemical liquid to the substrate; and
an adjusting unit configured to supply a chemical liquid of a first temperature and a chemical liquid of a second temperature to each of the plurality of nozzles in a predetermined ratio, the second temperature being higher than the first temperature,
wherein the adjusting unit supplies the chemical liquid of the second temperature in a higher ratio to a nozzle disposed at an outer circumference side of the substrate than to a nozzle disposed at a center side of the substrate, and
each of the nozzles supplies a chemical liquid in which the supplied chemical liquid of the first temperature and the supplied chemical liquid of the second temperature are mixed with each other, to the substrate.

2. The substrate processing apparatus of claim 1, wherein the adjusting unit includes:
a first inlet configured to allow inflow of the chemical liquid of the first temperature therethrough;
a second inlet configured to allow inflow of the chemical liquid of the second temperature therethrough;
a plurality of first supply ports having different diameters and communicating with the plurality of nozzles, respectively, the plurality of first supply ports being configured to supply the chemical liquid of the first temperature flowing therein from the first inlet; and
a plurality of second supply ports having different diameters and communicating with the plurality of nozzles, respectively, the plurality of second supply ports being configured to supply the chemical liquid of the second temperature flowing therein from the second inlet,
wherein the plurality of first supply ports is formed such that a first supply port nearer to the center of the substrate has a larger diameter and the plurality of second supply ports is formed such that a second supply port nearer to the outer circumference of the substrate has a larger diameter.

3. The substrate processing apparatus of claim 2, wherein the adjusting unit further includes:
a body having an internal space extending in a direction in which the nozzles are arranged, the nozzles being connected to a lower portion of the body; and
a partition member configured to partition the internal space of the body into a first space and a second space which are adjacent to each other at left and right sides when viewed in the direction where the nozzles are arranged, and
wherein the plurality of first supply ports is formed in a lower portion of the first space,
the plurality of second supply ports is formed in a lower portion of the second space,
the chemical liquid of the first temperature flowing in from the first inlet is supplied to the plurality of nozzles through the first space and the plurality of first supply ports, and
the chemical liquid of the second temperature flowing in from the second inlet is supplied to the plurality of nozzles through the second space and the plurality of second supply ports.

4. The substrate processing apparatus of claim 3, wherein the first inlet is formed in one of a sidewall positioned at the center side of the substrate and a sidewall positioned at the outer circumference side of the substrate, in the body, and the second inlet is formed in the other sidewall.

5. The substrate processing apparatus of claim 4, wherein the first inlet is formed in the sidewall positioned at the outer circumference side of the substrate, and
the second inlet is formed in the sidewall positioned at the center side of the substrate.

6. The substrate processing apparatus of claim 3, wherein the partition member is disposed such that the first space has a narrowest width at a side of a first supply port having a smallest diameter among the first supply ports and the second space has a narrowest width at a side of a second supply port having a smallest diameter among the second supply ports.

7. The substrate processing apparatus of claim 3, wherein the lower portion of the body positioned at a first space side is inclined such that a height thereof is reduced toward a first supply port having a smallest diameter from a first supply port having a largest diameter, and
the lower portion of the body positioned at a second space side is inclined such that a height thereof is reduced toward a second supply port having a smallest diameter from a second supply port having a largest diameter.

8. The substrate processing apparatus of claim 3, wherein each of the nozzles has a mortar shape with a width being gradually reduced toward an ejecting port.

9. The substrate processing apparatus of claim 1, wherein the adjusting unit includes:
a first piping portion including branch pipes and being supplied with the chemical liquid of the first temperature from a supply source, the number of the branch pipes being equal to or larger than the number of nozzles;
a second piping portion including branch pipes and being supplied with the chemical liquid of the second temperature from a supply source, the number of branch pipes being equal to or larger than the number of the nozzles;
a plurality of connection portions that connects the branch pipes of the first piping portion and the branch pipes of the second piping portion, respectively;
a plurality of third piping portions that connects the plurality of connection portions and the plurality of nozzles, respectively;
a plurality of first flow rate adjusting units which is provided in the plurality of branch pipes of the first piping portion, respectively, to adjust a flow rate of the chemical liquid of the first temperature; and
a plurality of first flow rate adjusting units which is provided in the plurality of branch pipes of the second piping portion, respectively, to adjust a flow rate of the chemical liquid of the second temperature,
wherein the plurality of first flow rate adjusting units is configured such that a first flow rate adjusting unit corresponding to a nozzle nearer to the center of the substrate supplies a higher flow rate of the chemical liquid of the first temperature to a downstream side, and the plurality of second flow rate adjusting units is configured such that a second flow rate adjusting unit corresponding to a nozzle nearer to the outer circumference of the substrate supplies a higher flow rate of the chemical liquid of the second temperature to a downstream side.

10. A liquid supply apparatus comprising:
a plurality of nozzles configured to supply a chemical liquid to a substrate; and
an adjusting unit configured to supply a chemical liquid of a first temperature and a chemical liquid of a second temperature to each of the plurality of nozzles in a predetermined ratio, the second temperature being higher than the first temperature,
wherein the adjusting unit includes:
a first inlet configured to allow inflow of the chemical liquid of the first temperature therethrough;
a second inlet configured to allow inflow of the chemical liquid of the second temperature therethrough;
a plurality of first supply ports having different diameters and communicating with the plurality of nozzles, respectively, the plurality of first supply ports being configured to supply the chemical liquid of the first temperature flowing therein from the first inlet; and
a plurality of second supply ports having different diameters and communicating with the plurality of nozzles, respectively, the plurality of second supply ports being configured to supply the chemical liquid of the second temperature flowing therein from the second inlet,
wherein the plurality of first supply ports is formed such that a first supply port nearer to the center of the substrate when supplying the chemical liquid to the substrate has a larger diameter and the plurality of second supply ports is formed such that a second supply port nearer to the outer circumference of the substrate when supplying the chemical liquid to the substrate has a larger diameter.
